(19) United States
(12) Patent Application Publication
(10) Pub. No.: US 2026/0371483 A1
(43) Pub. Date: Nov. 19, 2026

(54) ARTICLES COMPRISING AN INSULATING LAYER SUITABLE FOR ELECTRONIC ARTICLES AND METHODS

(71) Applicant: 3M INNOVATIVE PROPERTIES COMPANY, St. Paul, MN (US)

(72) Inventors: Chao Yang, Shanghai (CN); Yuan Zhao, Shanghai (CN); Zhiyong Xu, Shanghai (CN); Jule Sun, Shanghai (CN); Wei Li, Shanghai (CN)

(21) Appl. No.: 19/118,929

(22) PCT Filed: Dec. 13, 2023
(86) PCT No.: PCT/IB2023/062604

§ 371 Date: Apr. 7, 2025

(30) Foreign Application Priority Data
Dec. 22, 2022 (CN) 202211655642.6

(51) Int. Cl. H05K 1/09; H05K 1/02; H05K 1/03

(52) U.S. Cl. CPC H05K 1/095; H05K 1/0224; H05K 1/0326; H05K 2201/0129; H05K 2201/0145; H05K 2201/0278

(57) ABSTRACT

Electronic articles having an electromagnetic interference (EMI) shield and methods are described. The electronic articles comprise an (e.g. insulting) layer comprising a polymeric component. The conductive layer may comprise fibers and conductive particles or the conductive layer may comprise a substrate comprising me (e.g. printed circuit board) comprising adhesive. In one embodiment, the polymeric component comprises a block copolymer comprising hard blocks having cyclic moieties. In another embodiment, the polymeric component has a storage modulus of at least WMPa for a temperature range from 25 °C to 50 °C and a loss modulus of at least 1 MPa and less than 100 MPa at 100 °C.

### SUMMARY OF THE INVENTION

In one embodiment, an electronic article having an electromagnetic interference (EMI) shield is described comprising a first (e.g. insulting) layer comprising a polymeric component disposed on a conductive layer.

In one embodiment, the polymeric component comprises a block copolymer comprising hard blocks having cyclic moieties. In another embodiment, the polymeric component of the first insulating layer is characterized by specified Dynamic Mechanical Analysis (DMA) properties. In one embodiment, the polymeric component has a storage modulus of at least 10 MPa for a temperature range from 25 °C to 50 °C and a loss modulus of at least 1 MPa and less than 100 MPa at 100 °C.

In some embodiments, the conductive layer comprises fiber and conductive material. In some embodiments, the conductive layer further comprises an adhesive. The adhesive may comprise a thermosetting resin and conductive material.

In some embodiments, the electronic article further comprises a second (e.g. insulating and/or protective) layer disposed on the conductive layer. In some embodiments, the second layer may be different than the polymeric components of the first insulating layer, such as polyether ether ketone (PEEK). In other embodiments, the polymeric component of the second insulting layer has specified DMA properties, as previously described herein for the polymeric component of the first insulating layer. In some embodiments, the polymeric component of the second insulting layer is a block copolymer comprising hard blocks having cyclic moieties.

In another embodiment, a multilayer material is described comprising a conductive layer and an (e.g. insulating) layer disposed on the conductive layer. The polymeric component of the insulating layer is a block copolymer and/or characterized by specified Dynamic Mechanical Analysis (DMA) properties, as previously described.

In other embodiments, a method of providing an EMI shield on a substrate is described comprising:
a) providing a first insulating layer, as previously described, on a substrate;
b) applying a conductive layer comprising a thermosetting adhesive layer to the first insulating layer;
c) applying a second insulating layer to the conductive layer; and
d) applying heat and pressure at a temperature below the melt temperature of the first insulating layer at a temperature sufficient to cure the thermosetting material.

In some embodiments, the substrate comprises metal, such as conductive pathways including ground contact areas. In some embodiments, the method further comprises removing portions of the first insulating layer thereby exposing the ground contact areas.

In other embodiment, an article is described comprising a substrate comprising metal, inclusive of metal traces and an (e.g. insulating) layer comprising a polymeric component (e,g, block copolymer), as previously described.

### BRIEF DESCRIPTION OF THE DRAWINGS

FIG. 1 is the storage modulus of various polymeric components; and

FIG. 2 is the loss modulus of various polymeric components.

### WRITTEN DESCRIPTION

Presently described are articles and methods comprising an insulating layer comprising a polymeric material.

In one embodiment, the polymeric component of the insulating layer comprises a block copolymer. Block copolymer typically comprise hard blocks (also referred to as a hard segment) and soft blocks (also referred to as soft segments. The hard blocks often comprise a crystalline material, such as a material comprising aromatic moieties. One representative aromatic moiety is terephthalate. The soft blocks often contain a less crystalline or amorphous material, such as a saturated or unsaturated polyolefin. The polyolefin may further comprise heteroatoms, such as oxygen, such as in the case of polyethers. Such polymers may also be referred to as segmented polymers.

Block copolymer can have various structures. In some embodiments, the block copolymer may be characterized as linear, having alternating hard and soft blocks. Such polymers may also be referred to as segmented polymers. One general representation of such block copolymers is as follows.

(A-L-B)n

wherein A is a hard block, B is a soft block, L is a divalent linking group, and n is the number of alternating segments. The block copolymer may terminate with a hard block on one end and a soft block on the opposing end. Alternatively, the block copolymer may terminate with a hard block on both ends, a soften block on both ends, or a different end-capping group (that is not block A or block B.

In some embodiments, the divalent linking group is an ester moiety.

In some embodiments, the block copolymer is a thermoplastic polyester elastomer based on block copolymer technology commercially available from Dupont™ as the trade designation HYTREL™ Such thermoplastic polyester elastomer is a block copolymer comprising a hard (crystalline) segment of polybutylene terephthalate and a soft (amorphous) segment based on polyether chemistry.

One representative block copolymer, wherein the soft segment comprises polymerized units of alkyl (e.g. butyl) ether is depicted as follows.

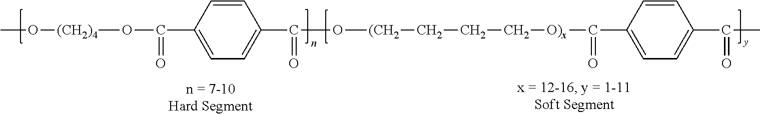

The polymeric component of the insulating layer may comprise a single (e.g. block copolymer) polymeric component as described above or a mixture of (e.g. block copolymer) polymeric components. The insulating layer may also comprise a mixture of a (e.g. block copolymer) polymeric component having the DMA properties previously described in combination with (e.g. small concentrations) of a polymeric component that does not have the DMA properties previously described. Although the present invention is exemplified with reference to thermoplastic polyester block copolymers, it is surmised that other (e.g. block copolymer) polymeric components can provide the properties described herein.

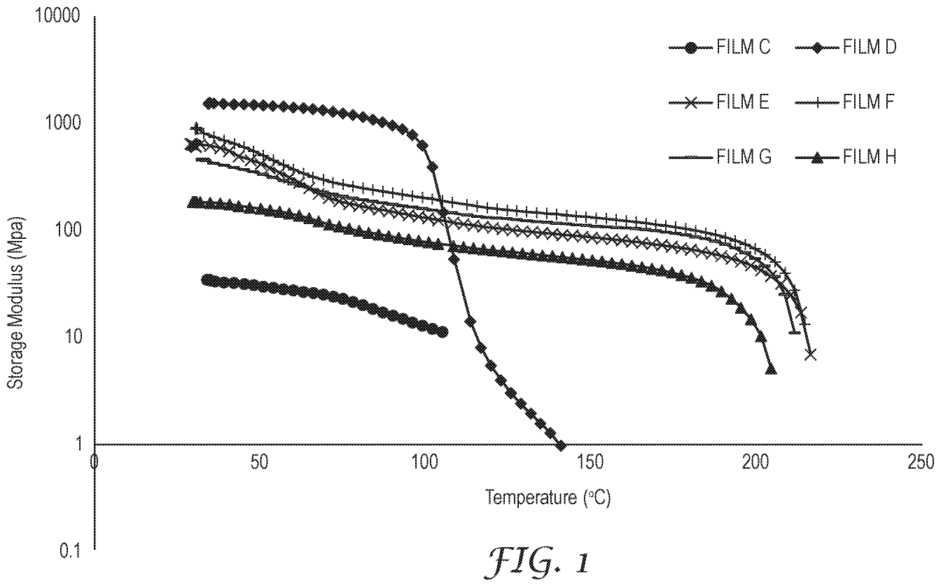

FIG. 1 is the storage modulus of various polymeric components. Film C is an illustrative (e.g. aromatic polycarbonate/polyether-based) thermoplastic polyurethane (TPU) polymer. Film D is an illustrative acrylonitrile butadiene styrene (ABS) polymer. Films E, F, G, and H comprise illustrative block copolymers. Such block copolymer comprises hard blocks comprising cyclic moieties.

With reference to FIG. 1, all these polymeric components have a sufficient storage modulus at lower temperatures. Notably, these polymeric components have a storage modulus of at least 10 MPa for a temperature range from 25 °C to 50 °C.

With reference to FIG. 1, in some embodiments, the (e.g. block copolymer) polymeric component (e.g. Films E, F, G, and H) has a sufficiently high storage modulus of 10 MPa at a temperature of at least 75, 100, 125, 150, 175, 200 °C. In some embodiments, the (e.g. block copolymer) polymeric component (e.g. Films E, F, G, and H) has a storage modulus of at least 20, 30, 40, 50, 60, 70, 80, 90 or 100 MPa for a temperature range from 25 °C to 50 °C. Notably, some of these storage modulus values are greater than the material of Film C. In some embodiments, the (e.g. block copolymer) polymeric component (e.g. Films E, F, G, and H) has a storage modulus of at least 10, 20, 30, 40, 50, 60, 70, 80, 90 or 100 MPa at a temperature of at least 75, 100, 125, 150, 175, 200 °C. Notably, the materials of Films C and D do not have a storage modulus of at least 10 MPa at a temperature of 125 °C or greater.

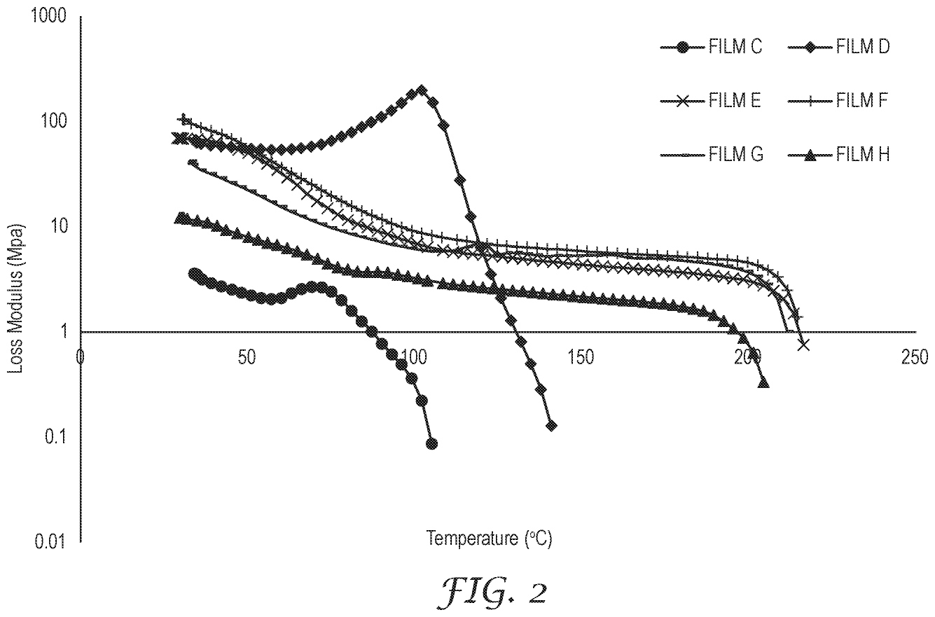

With reference to FIG. 2, the (e.g. block copolymer) polymeric material (e.g. Films E, F, G, and H) have a greater loss modulus at higher temperatures than the material of Films C or D. Notably, the (e.g. block copolymer) polymeric material (e.g. Films E, F, G, and H) have a loss modulus of at least 1 MPa and less than 100 MPa at 100 °C. Such loss modulus property is useful for thermally bonding and thermoforming. In one embodiment, e.g. block copolymer) polymeric component can be heat laminated to a substrate, such as a printed circuit board, at a temperature of 140 °C and air pressure of 0.6 MPa for a time of 60 second.

With reference to FIG. 2, in some embodiments, the (e.g. block copolymer) polymeric component has a loss modulus of less than 90, 80, 7, 60, 50, 40, 30, 20 or 10 MPa at 100 °C. In some embodiments, the (e.g. block copolymer) polymeric component has a loss modulus of at least 1 MPa at a temperature of at least 110, 120, 130, 140, 150, 160, 170, 180, 190 or 200 °C. In some embodiments, the (e.g. block copolymer) polymeric component has a loss modulus of less than 100, 90, 80, 7, 60, 50, 40, 30, 20 or 10 MPa at a temperature of at least 110, 120, 130, 140, 150, 160, 170, 180, 190 or 200 °C.

The storage modulus and loss modulus of the (e.g. block copolymer) polymeric component can be determined using Dynamic Mechanical Analysis (according to the test method further described in the examples).

Suitable (e.g. block copolymer) polymeric components typically have a melting temperature (as determined using ISO 527) of at least 150, 160, 170, 180, 190, 200, 210 or 220 °C. In some embodiments, the melting temperature is typically no greater than 230 or 225 °C. The Viscat softening temperature is typically about 10 °C lower than the melt temperature.

Suitable (e.g. block copolymer) polymeric components typically have a Melt Flow Rate (MFR) (e.g. 2.16 kg at 240 °C according to ASTM D1238) ranging from 10 to 30 g/10 min. In some embodiments, the MFR is less than 25, 20, or 15 g/10 min. The MFR is indicative of the molecular weight.

Suitable (e.g. block copolymer) polymeric components typically have a tensile strength at break of at least 25, 30, 35, 40, 45 or 50 MPa (according to ISO 527). In some embodiments, the tensile strength at break is no greater than 60, 55, 50, 45, or 40 MPa.

Suitable (e.g. block copolymer) polymeric component typically have a glass transition temperature (Tg) according to ISO 11357 of at least −40, −30, or −20 °C ranging up to 25, 30, 35, 40, 45, or 50 °C. Polymeric components having a Tg below zero can be favored for (e.g. the first) insulating layers disposed between the substrate and outer protective (e.g. second) insulating layer. Polymeric components having a Tg of at least 30, 35, 40, 45, or 50 can be favored for (e.g. the second) insulating outer protective (e.g. second) insulating layer.

Suitable (e.g. block copolymer) polymeric component typically have an elongation at break of at least 200, 250, 300, 350, 400, 450, 500, 550, or 600% (according to ISO 527). In some embodiments, the elongation at break is no greater than 1000, 900, 800, 700, 600, or 500%. As the film thickness of the (e.g. block copolymer) polymeric component decreases, the elongation can increase. For example, a 20-35 micron film can exhibit an elongation about twice the elongation value according to ASTM D 638. High elongation can provide more conformable insulating layers. However, when the elongation is too high the film tensile strength of the insulating layer may be insufficient.

The (e.g. block copolymer) polymeric component may be used as an insulating layer in various electronic article or components thereof, some of which are subsequently described.

The insulating layer typically has a thickness of at least 5 or 10 microns. In some embodiments, the insulating layer is at least 15, 20, 25, or 30 microns. In some embodiments, the insulating layer is at least 35, 40, 45, or 50 microns. In some embodiments, the insulating layer is at least 70, 70, 80, 90, or 100 microns. In some embodiments, the insulating layer is at least 150, 200, or 250 microns. It is typically preferred to minimize the thickness of the insulating layer, while providing a sufficient thickness to obtain the desired properties. In some embodiments, the insulating layer is no greater than 1 mm, 750 micron, 500 microns, 250 microns, 100 microns, 50 microns, or 25 microns.

In some embodiments, the articles and methods further comprise a conductive layer. The conductive layer typically comprises a woven or nonwoven (e.g. thermoplastic) fibers and conductive material. The (e.g. thermoplastic) fibers may comprise various thermoplastic materials such as polyesters (e.g., PET). The nonwoven further comprises a metal layer. The metal layer may be applied by chemical plating or electroplating.

The metal of the nonwoven can be made from a variety of materials. Preferred metals include elemental silver, gold, copper, nickel and chrome, with silver being especially preferred. Alloys such as stainless steel or dispersions containing these metals in admixture with one another or with other metals also can be employed. When additional metal layers are employed, they can be the same as or different from one another, and need not have the same thickness. Preferably the metal layer or layers are sufficiently thick so as to remain continuous when processed (e.g. as described herein), yet sufficiently thin so as to ensure that the film and articles employing the film will have the desired degree of EMI shielding and light transmission. The physical thickness (as opposed to the optical thickness) of the metal layer or layers is typically about 3 to about 50 nm, more preferably about 4 to about 15 nm.

The thickness of the conductive (e.g. non-woven) layer is typically at least 10 or 15 microns and typically no greater than 100, 75, or 50 microns (when measured according to ASTMD3652).

The surface resistance of the conductive (e.g. non-woven) layer is typically less than 0.10, or 0.05 (when measured according to ASTM F390).

The shielding effectiveness (at 10 MHz-3 GHz) of the conductive (e.g. non-woven) layer is typically at least 50, 60 or 70 bB (when measured according to SJ20524-1995).

The conductive (e.g. non-woven) layer typically has low elongation at break at room temperature. However, the elongation increases at higher temperatures. In some embodiments, the elongation at room temperature is no greater than 5, 4, 3, 2, or 1%. In some embodiments, the elongation at 120 °C is less than 10% or 5%. At 150 °C or 180 °C the elongation is typically at least 15, 20, 25, 30, 35, 40, 45, or 50%.

In some embodiments, the elongation at 150 °C or 180 °C the elongation is no greater than 50, 45, 40, 35, 30, 25, 20, or 15%. Higher elongation at elevated temperature is amenable to thermoforming the conductive (e.g. non-woven) layer.

The conductive (e.g. non-woven) layer typically comprises an adhesive. The adhesive may be present on the surface of the conductive (e.g. non-woven) layer that bonds to the insulating layer and/or on the opposing surface of the conductive (e.g. non-woven) layer (e.g. that can be bonded to a second (e.g. insulating) layer. In some embodiments, the adhesive has a thickness on a least one surface of the conductive (e.g. non-woven) layer of at least 10, 15, 20, 25, or 30 microns. In some embodiments, the adhesive has a thickness on a least one surface of the conductive (e.g. non-woven) layer of no greater than 50, 40, 30, or 30 microns. The adhesive can be applied by an suitable method. In some embodiments, the adhesive is applied using the method described in WO2022246682

In some embodiments, the adhesive is a thermosetting resin. Suitable thermosetting resin composition include for example phenol resins, an epoxy resin composition, a urethane resins, a melamine resins, silicone resins and alkyd resins.

In some embodiments, the adhesive comprises an epoxy resin. Useful epoxy resins or epoxides comprises at least one oxirane ring that is polymerizable by ring opening, i.e., an average epoxy functionality greater than one, and preferably at least two. The epoxides can be monomeric or polymeric, and aliphatic, cycloaliphatic, heterocyclic, aromatic, hydrogenated, or combinations thereof. Preferred epoxides contain more than 1.5 epoxy group per molecule and preferably at least 2 epoxy groups per molecule. The useful materials typically have a weight average molecular weight of about 150 to about 10,000, and more typically of about 180 to about 1,000.

Epoxy resins include aromatic glycidyl ethers, e.g., such as those prepared by reacting a polyhydric phenol with an excess of epichlorohydrin, cycloaliphatic glycidyl ethers, hydrogenated glycidyl ethers, and mixtures thereof.

Other epoxy resins that are useful include the cycloaliphatic epoxies, such as dicyclopentadiene epoxy resins, available under the trade designation HP 7200 from DIC Corporation, Tokyo, Japan Epoxy equivalent weight 250-280 g/eq, softening point 57-68 °C, 0.1-2.0 dPa·sec at 150 °C.

The epoxy resin typically cures below the melting temperature of the insulating layer. When the conductive layer is thermoformed. The epoxy resin cures at the thermoforming temperature. In some embodiments, the epoxy resin begins curing at a temperature of 150 °C. The curing is accelerated at higher temperatures such as the lamination temperature (e.g. 190 °C).

In some embodiments, the adhesive comprises electrically conductive particles. Suitable conductive particles include for example metal fine particles, carbon nanotubes, carbon fibers, metal fibers, and the like. Suitable metal fine particles include for example conductive particles comprise nickel, copper, silver, or a combination thereof. In some embodiments, the conductive particles comprise copper powder plated with other metals such as nickel or silver.

The shape of the conductive particles may be spherical, a flat shape, a scale shape, a dendritic shape, a rod shape, a fiber shape, and the like.

The average particle diameter of the conductive particles typically ranges from 0.5 to 50 microns. In some embodiments, the conductive particles comprises conductive particles having a particle size of less than 10 or 5 microns optionally in combination with conductive particle having a particle size of at least 15, 20 or 25 microns. The with ratio of smaller particle to larger particle can range from 2:1 to 1:2.

The amount of conductive particles is typically at least 5, 10, 15, 20, or 25 wt. %. The amount of conductive particle is typically no greater than 40 or 50.

The conductive adhesive layer may further comprise various additive as known in the art including curing accelerator, a tackifier, an antioxidant, a pigment, a dye, a plasticizer, a UV absorber, an antifoaming agent, a leveling agent, a filler, a flame retardant.

The (e.g. nonwoven) conductive layer in combination with the adhesive layer preferably has a contact resistance (as measured according to the test method of the examples) of less than 200 mOhm. In some embodiments, the contact resistance is less than 150, 100, 75, or 50 mOhm. The (e.g. nonwoven) conductive layer in combination with the adhesive layer preferably has a SE at 10 GHz (as measured according to the test method of the examples) in a range from −45 to −80 db. In some embodiments, the SE at 10 GHz at least −55, or −65 db.

Methods of providing an EMI shield on a substrate are also described.

In one embodiment, the method comprises a) providing a first insulating layer on a substrate wherein the first insulating layer comprises a polymeric component having specific DMA properties as previously described and/or comprises a block copolymer comprising cyclic hard blocks.

The first insulting layer may be prepared into a film by melt extrusion of the polymeric component (e.g. block copolymer). The preformed film may be bonded to the substrate by various technique including heat lamination. In some embodiments, the insulating material layer is hot-pressed on a substrate (e.g. circuit board) at a temperature between 120 °C and 220 °C. In some embodiments, the temperature is at least 130, 140, 150 or 160 °C. In some embodiments, the temperature is no greater than 210, 200, 190, 180, 170, 160, or 150 °C.

The method further comprises b) applying a conductive layer comprising a (e.g. thermosetting) adhesive layer to the first insulating layer. An adhesive is typically pre-applied to the conductive layer in a separate step, as previously described.

The method further comprises c) applying a second insulating layer to the conductive layer. The second insulating layer may comprise various thermoplastic materials including polyolefin, polyethylene terephthalate, polycarbonate, polyetherether ketone. In some embodiments, the second insulating layer comprises a thermoplastic material having melting temperature of at least 200 °C. In some embodiments, the second insulating layer comprises a polymeric component having the properties claimed for the polymeric component of the first insulating layer. In some embodiments, the second insulating layer comprises a block copolymer.

The method further comprises d) applying heat and pressure at a temperature below the melt temperature of the first insulating layer and at a temperature sufficient to cure the thermosetting adhesive layer. In some embodiment, this step also comprises (e.g. concurrently) thermoforming the conductive (e.g. nonwoven) layer to the substrate (e.g. printed circuit board). This temperature is also between 120 °C and 220 °C. In some embodiments, the temperature is at least 130, 140, 150 or 160 °C. In some embodiments, the temperature is no greater than 210, 200, 190, 180, 170, 160, or 150 °C. This temperature is sufficiently above the glass transition temperature of the second insulating layer such that a thermal bond can be formed. However, this temperature is typically below the melting temperature of the first insulating layer.

In some embodiments, such an in the case of printed circuit boards, the substrate comprises conductive pathways including ground contact areas.

In this embodiment, the method typically further comprising removing portions of the first insulating layer thereby exposing the ground contact areas.

In one embodiments, an article is described comprising a substrate comprising metal, inclusive of metal traces, and an insulating layer comprising a polymeric component comprising a block copolymer comprising hard segments comprising cyclic moieties.

The conductive layer of the EMI shield is typically connected to at least one grounding electrode as known in the art. The grounding electrode(s) can be connected to the metal layer(s) before or after the EMI shielding film is joined to other materials or to a device requiring EMI shielding. Grounding electrodes can be formed using masking, plating and other printed circuitry techniques or formed using metallic strips, wires, conductive paints, as well as conductive adhesive and tapes.

In another embodiments, the metal layer need not be grounded. Applications for such ungrounded EMI shielding films include testing facilities, security/secure rooms, antennae components.

Also described are various articles and components of an electronic article.

In one embodiment, an article is described comprising a substrate comprising metal, inclusive of metal traces, and an insulating layer disposed on the substrate. The insulating layer comprises a polymeric component comprising a block copolymer and/or has specified DMA properties, as previously described. In one embodiment, the substrate is a printed circuit board.

In another embodiment, a multilayer article is described a conductive layer and a second (e.g. insulating) layer disposed on conductive layer. The conductive layer comprises an adhesive, as previously described. The second (e.g. insulating layer comprises a polymeric component that comprises a block copolymer and/or has specified DMA properties, as previously described.

### Examples

Unless otherwise noted or readily apparent from the context, all parts, percentages, ratios, etc. in the Examples and the rest of the specification are by weight.

The following abbreviations are used in this section: g=grams, μm=micrometers, mm=millimeters, m=meters, s=seconds, min=minutes, °C=degrees Celsius, MPa=megapascals, GHz=gigahertz, db=decibels, mOhm=milliohms, EMI=electromagnetic interference. Abbreviations for materials used in this section, as well as descriptions of the materials, are provided in Table 1.

TABLE 1
Materials Used in the Examples

| Abbreviation | Description and Source |
|---|---|
| RESIN A | Thermoplastic Polyester Elastomer resin available under the trade designation |
| | DUPONT HYTREL 8238 from DuPont, Wilmington, DE |
| FILM B | Unfilled semi-crystalline polyether ether ketone (PEEK) film with a thickness |
| | of 6 μm, available under the APTIV PEEK film, VICTREX, Thornton- |
| | Cleveleys, UK |
| RESIN C | Aromatic polycarbonate/polyether-based thermoplastic polyurethane (TPU) |
| | resin available under the trade designation ESTANE TS85AP3 available from |
| | The Lubrizol Corporation, Wickliffe, OH |
| FILM D | Acrylonitrile Butadiene Styrene (ABS) film with 100 μm thickness, available |
| | from Ningbo CFM New Materials Co., China |
| RESIN G | Thermoplastic Polyester Elastomer resin available under the trade designation |
| | DUPONT HYTREL 7246 from DuPont |
| RESIN H | Thermoplastic Polyester Elastomer resin available under the trade designation |
| | DUPONT HYTREL 5556 from DuPont |
| CONDUCTIVE | Non-woven polyester cloth substrate with copper and nickel metal layers, with |
| LAYER A | thickness 0.04 ± 0.01 mm and weight of 40 ± 10 g/m², available under trade |
| | designation WF37B from Zhejiang Saintyear Electronic Technologies Co., |
| | LTD., China |
| CONDUCTIVE | Non-woven PET felt with chemical plated and electroplated metal layer, with |
| LAYER B | thickness 0.015 ± 0.003 mm, available under trade designation WR36C from |
| | Zhejiang Saintyear Electronic Technologies Co., LTD. |
| ADHESIVE A | Epoxy Resin (dicyclopentadiene type), available under the trade designation |
| | HP 7200 from DIC Corporation, Tokyo, Japan Epoxy equivalent weight 250- |
| | 280 g/eq, softening point 57-68 °C, 0.1-2.0 dPa · sec at 150 °C. |
| FILLER A | Nickel Powder with particle size D50 of 5.0 μm available under the trade |
| | designation P503 from Jiaxing, China |
| FILLER B | Nickel Coated Copper, 50 wt % Ni, average particle size 5 μm, available under |
| | the trade designation NC05F50 from Potters Industries, LLC, PA, USA |
| FILLER C | Silver Coated Copper, dendritic shaped, 20 wt % Ag, average particle size 28 |
| | um, available under the trade designation SC25D20 from Potters Industries, |
| | LLC |
| LINER | PET liner available under the trade designation PT25BTB18 from Jiangsu |
| | Maxgon New Material Technology Co. Ltd, China |

### Test Methods

### EMI Testing Method

Electromagnetic shielding effectiveness (SE) of samples was measured according to ASTM D4935-18. The SE at a frequency of 10 GHz is reported in Table 3.

### Contact Resistance Method

Samples were prepared by cutting strips of 12.7 mm width conductive layer material. Conductivity was tested by placing the sample, adhesive side down, on a linear array of ½ oz (14 g) Cu conductor strips, 260 μm wide, arranged with a uniform 200 μm pitch. A 2 kg rubber roller was shuttled once over the tape. After 5 min of dwell time at 170 °C, the DC resistance between adjacent electrodes was measured with ohm meter available under the trade designation RM3545-01 from Hioki E.E. Corporation, Plano, TX, and the highest resistance value observed was recorded. The test result was insensitive to the length of the conductor strips or the distance between the ohm meter probes and the sample because the resistance of the sample was much greater than that of the conductor strips.

### Dynamic Mechanical Analysis (DMA) Method

The measurements were performed using a Q800 DMA available from TA Instruments, Newcastle, DE, operated in Tension mode via temperature ramp with the frequency of 1 Hz and strain of 0.2% to observe the sample mechanical properties. Film samples were prepared by first punched out to a sample length more than 24 mm and a width of 5.5 mm. The sample was then installed in the DMA film clamps. The distance between the two clamps was between 8 and 20 mm. The storage modulus, loss modulus and loss factor (tan delta) were determined as a function of temperature at a constant frequency.

### Preparative Examples

FILMS A, C, E, F, G, and H were prepared by extrusion of the resins at extruder temperatures between 190 and 250 °C. The film thickness is provided in Table 2.

TABLE 2
Film Thickness

| | | Thickness |
|---|---|---|
| FILM | Resin | (μm) |
| FILM A | RESIN A | 30 |
| FILM C | RESIN C | 50 |
| FILM E | RESIN A | 100 |
| FILM F | RESIN F | 200 |
| FILM G | RESIN G | 100 |
| FILM H | RESIN H | 80 |

### EXAMPLES

For Examples 1 through 3 (EX-1 through EX-3), EMI shield layers were prepared by coating an adhesive indicated in Table 3 by slot die coater on one side of the conductive nonwoven indicated in Table 3 at a coating speed of 1 m/min and an oven temperature of 105 °C and laminating LINER to the other side. Sample thickness was measured with a thickness meter as reported below. The adhesive penetrates the nonwoven and thus is present on both sides. SE and contact resistance were measured for these Examples and Comparative Example according to the EMI Testing Method and Contact Resistance Method. Thickness, SE, and contact resistance are reported in Table 4.

TABLE 3
Materials

| Example or | | ADHE- | | | |
|---|---|---|---|---|---|
| Comparative | Conductive | SIVE | FILLER | FILLER | FILLER |
| Example | Nonwoven | A (g) | A (g) | B (g) | C (g) |
| EX-1 | CONDUCTIVE | 100 | 10 | 10 | 5 |
| | LAYER A | | | | |
| EX-2 | CONDUCTIVE | 100 | 10 | 10 | 0 |
| | LAYER A | | | | |
| EX-3 | CONDUCTIVE | 100 | 20 | 0 | 0 |
| | LAYER B | | | | |

TABLE 4
Characterization

| Example or | Adhesive | | Contact |
|---|---|---|---|
| Comparative | Thickness | SE at 10 | Resistance |
| Example | (μm) | GHz (db) | (mOhm) |
| Target | | −45 to −80 | <200 |
| Value | | db | |
| EX-1 | 33 | -74 | 45 |
| EX-2 | 31 | -75 | 80 |
| EX-3 | 16 | -65 | 553 |

For Example 4 (EX-4), a thermally formed conformal EMI shield was prepared as follows. FILM A was placed on a printed circuit board (PCB) and a film laminator built by Kingdao Technology, Shenzhen, China, was used to conform the film to the PCB. The film laminator shaping cavity applied heat and air pressure over the film to conform it to the PCB. The laminator was set to apply a temperature of 140 °C and air pressure of 0.6 MPa for 60 s. Next, areas of FILM A overlaying ground contact areas of the PCB were removed by laser cutting. Next, EX-1 was placed over the PCB, with the adhesive coating in contact with FILM A, and FILM B was placed on top of EX-1. The laminator was then set to apply a temperature of 190 °C and air pressure of 1 MPa to the sample for 60 s. During heat lamination the adhesive penetrates EX-1 and also bonds FILM B. Although FILM A is not shown in FIG. 1 or 2, FILM A would have the same storage modulus and loss modulus properties as FILM E and F that were also prepared from Resin A.

1-23. (canceled)

24. An electronic article according to claim 26, wherein the conductive layer comprises metal, inclusive of metal traces.

25. (canceled)

26. An electronic article having an EMI shield comprising:
a first (e.g. insulting) layer comprising a polymeric component having a storage modulus of at least 10 MPa for a temperature range from 25 °C to 50 °C; and a loss modulus of at least 1 MPa and less than 100 MPa at 100 °C; and
a conductive layer disposed on the first (e.g. insulating) layer.

27. The electronic article of claim 26 wherein the polymeric component has one or more of the following properties:
a) a storage modulus of greater than 10 MPa at a temperature of at least 75, 100, 125, 150, 175, 200 °C;
b) a storage modulus of at least 20, 30, 40, 50, 60, 70, 80, 90 or 100 MPa for a temperature range from 25 °C to 50 °C;
c) a storage modulus of at least 20, 30, 40, 50, 60, 70, 80, 90 or 100 MPa at a temperature of at least 75, 100, 125, 150, 175, 200 °C.

28. The electronic article of claim 26 wherein the polymeric component has one or more of the following properties:
a) a loss modulus of less than 90, 80, 7, 60, 50, 40, 30, 20 or 10 MPa at 100 °C;
b) a loss modulus of at least 1 MPa at a temperature of at least 110, 120, 130, 140, 150, 160, 170, 180, 190 or 200 °C;
c) a loss modulus of less than 100, 90, 80, 7, 60, 50, 40, 30, 20 or 10 MPa at a temperature of at least 110, 120, 130, 140, 150, 160, 170, 180, 190 or 200 °C.

29. The electronic article of claim 26 wherein the polymeric component has a melting temperature of at least 200 °C.

30. The electronic article of claim 26 wherein the polymeric component has an elongation at break of at least 200, 250, 300, or 350%

31. The electronic article of claim 26 wherein the polymeric component comprises a block copolymer comprising hard segments with cyclic moieties.

32. The electronic article of claim 26 wherein in the conductive layer comprises thermoplastic fibers and conductive material.

33. The electronic article of claim 26 wherein the conductive layer further comprises an adhesive that comprises a thermosetting resin and conductive material.

34. The electronic article of claim 33 wherein the thermosetting resin is an epoxy resin.

35. The electronic article of claim 33 wherein the conductive material comprises conductive particles ranging in size from 5 to 25 microns

36. The electronic article of claim 26 wherein the electronic article further comprises a second (e.g. insulating) layer disposed on the conductive layer, wherein the second (e.g. insulating) layer has a melting temperature of at least 200 °C.

37. The electronic article of claim 26 wherein the second (e.g. insulating) layer comprises a polymeric component having the properties claimed for the polymeric component of the first (e.g. insulating) layer.

38. The electronic article of claim 26 wherein the EMI shield is disposed upon a substrate further comprising conductive pathways.

39. The electronic article of claim 38 wherein the conductive layer is electrically connected to the conductive pathways of the substrate through the one or more through holes in the first insulating layer.

40. The electronic article of claim 26 wherein the substrate is a printed circuit board.

41. A multilayer material comprising:
a conductive layer; and
an insulating layer disposed on the conductive layer wherein the insulating layer comprises a polymeric component having a storage modulus of at least 10 MPa for a temperature range from 25 °C to 50 °C and a loss modulus of at least 1 MPa and less than 100 MPa at 100 °C.

42-48. (canceled)
